(19) United States
(12) Patent Application Publication
(10) Pub. No.: US 2014/0016389 A1
(43) Pub. Date: Jan. 16, 2014

(54) DRAM MEMORY CELLS RECONFIGURED TO PROVIDE BULK CAPACITANCE

(71) Applicant: MOSAID TECHNOLOGIES INCORPORATED, Ottawa (CA)

(72) Inventors: Yonghua LIU, Ottawa (CA); James KOSOLOWSKI, Woodlawn (CA)

(73) Assignee: MOSAID TECHNOLOGIES INCORPORATED, Ottawa (CA)

(21) Appl. No.: 13/834,009

(22) Filed: Mar. 15, 2013

Related U.S. Application Data
(60) Provisional application No. 61/670,794, filed on Jul. 12, 2012.
(60) Provisional application No. 61/782,480, filed on Mar. 14, 2013.

(51) Int. Cl. G11C 11/401

(52) U.S. Cl. CPC G11C 11/401
USPC 365/63

(57) ABSTRACT

A semiconductor device includes a Dynamic Random Access Memory (DRAM) memory array. The DRAM memory array includes a plurality of DRAM memory cells. Each of the DRAM memory cells includes a capacitor. Switching circuitry within the semiconductor device is configured to be switched to a state in which the switching circuitry connects capacitors of at least two of the DRAM memory cells together to provide a bulk capacitance between a first node and a second node.

### CROSS-REFERENCE TO RELATED APPLICATION

The present application claims the benefit under 35 USC §119(e) of U.S. Provisional Patent Application Ser. No. 61/670,794, filed Jul. 12, 2012, and also U.S. Provisional Patent Application Ser. No. 61/782,480, filed Mar. 14, 2013, and both of the above-mentioned applications are incorporated herein by reference in their entireties.

### BACKGROUND

Dynamic Random Access Memory (DRAM) is a type of semiconductor memory that stores each bit of data in a separate capacitor within an integrated circuit. The capacitor can be either charged or discharged; these two states are taken to represent the two values of a bit. Since capacitors leak charge, the information eventually fades unless the capacitor charge is refreshed periodically. Because of this refresh requirement, DRAM is a “dynamic” memory as opposed to a “static” memory.

A main advantage of DRAM is its structural simplicity: only one transistor and a capacitor are required per bit, compared to four or six transistors in SRAM. This allows DRAM to reach very high densities. This, in turn, makes DRAM relatively inexpensive to manufacture, when considering the cost per memory cell.

### SUMMARY

In accordance with an example embodiment, there is provided a DRAM memory cell array that includes a conventional portion and a novel portion. The novel portion of the DRAM memory cell array is reconfigured to provide a bulk capacitance functionality.

In accordance with another example embodiment, there is provided a semiconductor device including a plurality of DRAM memory cells. Each of the DRAM memory cells includes a capacitor. The semiconductor device also includes switching circuitry configured to be switched to a state in which the switching circuitry connects capacitors of at least two of the DRAM memory cells together to provide a bulk capacitance between a first node and a second node, such that the at least two DRAM memory cells are repurposed in the state.

In accordance with another example embodiment, there is provided a method of manufacture that includes producing a DRAM memory array that includes a plurality of DRAM memory cells. Each of the DRAM memory cells includes a capacitor. The method of manufacture also includes identifying at least two of the DRAM memory cells to be reconfigured. The method of manufacture also includes reconfiguring the identified memory cells by connecting the capacitors of the identified memory cells together to provide a bulk capacitance between a first node and a second node.

The method of manufacture may include testing the DRAM memory cells to identify failed cells, and identifying the failed cells as the at least two DRAM memory cells to be reconfigured.

The method of manufacture may include electrically isolating the at least two DRAM memory cells from other ones of the plurality of DRAM memory cells that are not failed cells.

In at least one example of the method of manufacture, the connecting of the capacitors may include programming at least one fuse in order to make the reconfiguring permanent.

In at least one example of the method of manufacture, the capacitors of the at least two DRAM memory cells may be connected in series.

In at least one example of the method of manufacture, the capacitors of the at least two DRAM memory cells may be connected in parallel.

In at least one example of the method of manufacture, each of the at least two DRAM memory cells may further include a transistor capable of being turned on or off based on a gate voltage.

In at least one example of the method of manufacture, the transistor of each of the at least two DRAM memory cells may be a MOS transistor.

In at least one example of the method of manufacture, for each of the at least two DRAM memory cells, the respective capacitor may have a first node and a second node, and the respective transistor may have a first node and a second node through which current flows when the transistor is turned on, and the second node of the respective transistor may be connected to the first node of the respective capacitor.

In at least one example of the method of manufacture, the second node of the capacitor of a first one of the at least two DRAM memory cells may be connected to the second node of the capacitor of a second one of the at least two DRAM memory cells.

In at least one example of the method of manufacture, the first node may be a first bulk capacitance node, the second node may be a second bulk capacitance node, the first bulk capacitance node may be connected to the first node of the transistor of a first one of the at least two DRAM memory cells, and the second bulk capacitance node may be connected to the first node of the transistor of a second one of the at least two DRAM memory cells.

In at least one example of the method of manufacture, the first node may be a first bulk capacitance node, the second node may be a second bulk capacitance node, the first bulk capacitance node may be connected to the first node of the transistor of each of the at least two DRAM memory cells, and the second bulk capacitance node may be connected to the second node of the capacitor of each of the at least two DRAM memory cells.

In at least one example of the method of manufacture, the DRAM memory array may include a plurality of DRAM memory cells other than the at least two DRAM memory cells, and which are configured for data storage.

In at least one example of the method of manufacture, the capacitor of each of the other DRAM memory cells may be connected to a common voltage reference.

In at least one example of the method of manufacture, the switching circuitry may include a circuit for isolating the capacitors of the at least two DRAM memory cells from the voltage reference.

In at least one example of the method of manufacture, the DRAM memory cells of the DRAM memory array may be arranged in a matrix of rows and columns, and the at least two DRAM memory cells may include DRAM memory cells from at least two of the columns of the DRAM memory array.

In at least one example of the method of manufacture, the DRAM memory cells of the DRAM memory array may be arranged in a matrix of rows and columns, and the at least two DRAM memory cells may include DRAM memory cells from at least two of the rows of the DRAM memory array.

In at least one example of the method of manufacture, the DRAM memory cells of the DRAM memory array may be arranged in a matrix of rows and columns, and each of the DRAM memory cells may be connected to a wordline for the respective row and to a bitline for the respective column, and the first node may be connected to a first one of the bitlines.

In at least one example of the method of manufacture, the second node may be connected to a second one of the bitlines.

In at least one example of the method of manufacture, the capacitor in each of the DRAM memory cells may be a metal-insulator-metal (MIM) capacitor.

In at least one example of the method of manufacture, the capacitor in each of the DRAM memory cells may be a stack-type capacitor.

In at least one example of the method of manufacture, the capacitor in each of the DRAM memory cells may be a trench-type capacitor.

In accordance with another example embodiment, there is provided a method that includes using a first portion of a DRAM memory cell array to provide a bulk capacitance in an electronic device, while a second portion of the DRAM memory cell array provides a data storage function.

In accordance with another example embodiment, there is provided a system that includes a primary circuit of an electronic device drawing power from a power source when the electronic device is in a normal mode of operation. The system also includes a semiconductor memory device that includes an array of DRAM memory cells. At least part of the memory device is configured to respond to a command to implement a data storage function or a bulk capacitive power supply function for the primary circuit. The system also includes a control circuit. The control circuit is responsive to receipt of a control signal to command the at least part of the memory device to implement the data storage function when the electronic device is in the normal mode of operation and to implement the bulk capacitive power supply function for the primary circuit when the electronic device is in a power saving mode of operation.

In at least one example of the system, the control circuit may be configured to disconnect the primary circuit from the power source when the semiconductor device implements the bulk capacitive power supply function.

In at least one example of the system, the primary circuit may include an SRAM cache.

In at least one example of the system, the primary circuit, the semiconductor device and the control circuit may all be within a single integrated circuit chip.

In at least one example of the system, the system may be implemented in a mobile communications apparatus.

In at least one example of the system, the control signal is indicative of an instruction to enter a power saving mode of the mobile communications apparatus.

### BRIEF DESCRIPTION OF THE DRAWINGS

Reference will now be made, by way of example, to the accompanying drawings:

FIG. 1A is a block diagram of an example DRAM memory cell array;

FIG. 1B is a block diagram of a portion of the DRAM memory cell array of FIG. 1A, illustrating a plurality of DRAM memory cells;

FIG. 2A is a block diagram of a portion of a DRAM memory cell array, in which switching circuitry enables a subset of the DRAM memory cells in different rows to be repurposed to provide a bulk capacitance functionality, in accordance with example embodiments;

FIG. 2B shows a path wherein the capacitors from two DRAM memory cells in different rows have been placed in series to provide a bulk capacitance, in accordance with an example embodiment;

FIG. 2C shows a path wherein the capacitors from two DRAM memory cells in different rows have been placed in parallel to provide a bulk capacitance, in accordance with an example embodiment;

FIG. 3 shows a switching element that can be used to override the voltage on a wordline;

FIG. 4A is a block diagram of a portion of a DRAM memory cell array, in which switching circuitry enables a subset of the DRAM memory cells in different columns to be repurposed to provide a bulk capacitance functionality, in accordance with example embodiments;

FIG. 4B shows a path wherein the capacitors from two DRAM memory cells in different columns have been placed in series to provide a bulk capacitance, in accordance with an example embodiment;

FIG. 4C shows a path wherein the capacitors from two DRAM memory cells in different columns have been placed in parallel to provide a bulk capacitance, in accordance with an example embodiment;

FIG. 5 is a circuit diagram of a voltage pump circuit which utilizes bulk capacitance provided by a memory device with repurposed DRAM memory cells in accordance with an example embodiment;

FIG. 6 is a functional block diagram of a system in which a dual-purpose memory array provides bulk capacitive power to a primary circuit during a power saving mode of operation of an electronic device, in accordance with an example embodiment;

FIG. 7 is a flowchart illustrating actions carried out by a circuit in the system of FIG. 6 in order to control the dual-purpose memory array;

FIG. 8 illustrates power being supplied to the primary circuit from a power supply during a normal mode of operation;

FIG. 9 illustrates power being supplied to the primary circuit from the dual-purpose memory array during a power saving mode of operation;

FIG. 10A-10C are more detailed version of FIGS. 2A-2C, respectively, as applied to an embedded DRAM circuit, in accordance with example embodiments;

FIG. 11A shows an embedded DRAM circuit configured to provide three terminals and two switching nodes, thereby to create a block for a variety of purposes, in accordance with an example embodiment;

FIG. 11B is a simplified circuit equivalent to that of FIG. 11A;

FIGS. 12A-12C illustrate the structure and operation of a DC-DC converter implementing a pair of blocks such as those of FIGS. 11A and 11B, in accordance with an example embodiment;

FIG. 13 is a block diagram of a switched-capacitor step-down DC-DC converter that uses blocks such as those of FIGS. 11A and 11B, in accordance with an example embodiment;

FIG. 14 is a block diagram of a high voltage charge pump that uses blocks such as those of FIGS. 11A and 11B, in accordance with an example embodiment;

FIG. 15A is a cross section of a semiconductor device in which two MIM capacitors are connected in parallel in accordance with a stack-type implementation;

FIG. 15B is a cross section of a semiconductor device in which two MIM capacitors are connected in series in accordance with a stack-type implementation;

FIG. 16A is a cross section of a semiconductor device in which two MIM capacitors are connected in parallel in accordance with a trench-type implementation;

FIG. 16B is a cross section of a semiconductor device in which two MIM capacitors are connected in series in accordance with a trench-type implementation; and

FIG. 17 is a flowchart of a manufacturing method, in accordance with an example embodiment.

It is to be expressly understood that the description and drawings are only for the purpose of illustration of certain example embodiments and are an aid for understanding. They are not intended to be a definition of the limits of the invention.

Similar or the same reference numerals may have been used in different figures to denote similar example features illustrated in the drawings.

### DETAILED DESCRIPTION

The term “bulk capacitance” as herein used refers to two or more capacitors interconnected in a manner so as to form an aggregated capacitance comprised of the two or more capacitors.

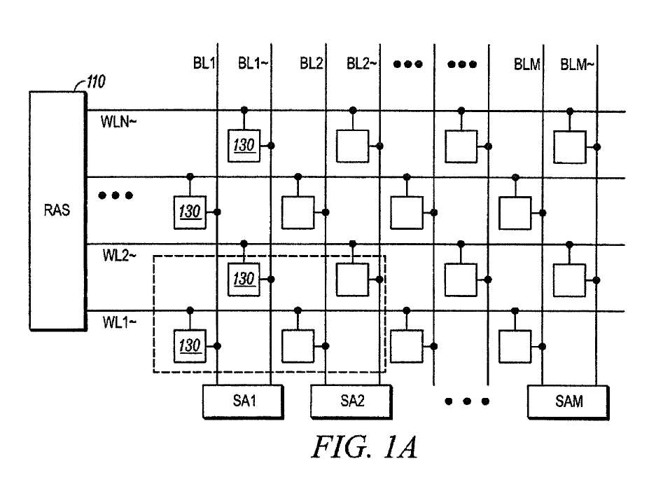

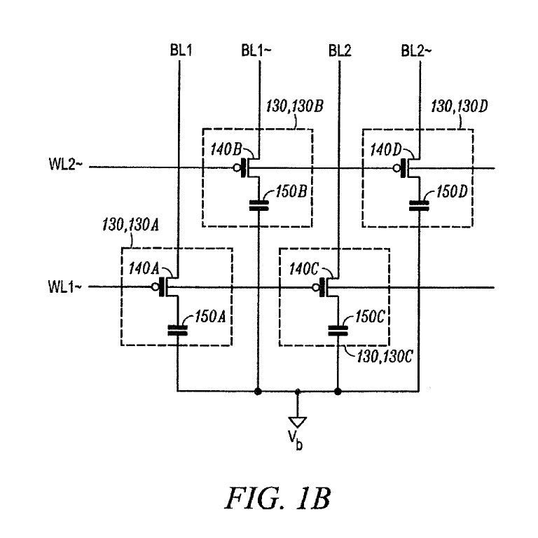

Reference is now made to FIG. 1A, which conceptually shows, in simplified form, an example DRAM memory cell array (or simply “DRAM array”), comprising a plurality of DRAM memory cells (or simply “DRAM cells”) 130 arranged in N rows and M columns. Each of the DRAM memory cells 130 is connected to a respective one of a plurality of wordlines WL1˜, WL2˜, . . . , WLN˜ and to a respective one of a plurality of bitlines BL1/BL1˜, BL2/BL2˜, . . . , BLM/BLM˜.

The wordlines are provided by a row address selector 110 and are used for selection of the DRAM memory cells in a given row of the DRAM memory cell array. The bitlines are used for reading or writing data to the DRAM memory cell occupying a selected column of the selected row. Specifically, the bitlines are arranged as folded bitlines (pairs of complementary bitlines) and each pair of complementary bitlines is connected to a corresponding one of a plurality of bitline sense amplifiers SA1, SA2, . . . , SAM. Thus, although a given one of the DRAM memory cells 130 may be shown as connected to only one bitline, the complementary bitline is actually used as a reference during sensing by the corresponding bitline sense amplifier.

For simplicity, the DRAM memory cell array may include other components. For example, the bitline sense amplifiers SA1, SA2, . . . , SAM are connected to databuses (not shown) through a pair of respective column access transistors (not shown). The pairs of column access transistors are activated by respective column address signals (not shown), when data access to the array is required. These components, as well as various isolation, pre-charge and equalization circuits, would be known to those of skill in the art and for simplicity have not been illustrated.

Each of the DRAM memory cells 130 includes an access transistor and a charge storage capacitor. This is now described in further detail, with reference to FIG. 1B, where there is shown a set of four memory cells 130A, 130B, 130C, 130D. The four memory cells are distributed over two rows and two columns. The two rows are identified by wordlines WL1 and WL2. The two columns are identified, respectively, by complementary bitline pair BL1/BL1˜ and complementary bitline pair BL2/BL2˜. Each of the DRAM memory cells 130A, 130B, 130C, 130D includes a respective transistor 140A, 140B, 140C, 140D and a respective capacitor 150A, 150B, 150C, 150D.

Consider now a given one of the memory cells, say 130A, with the understanding that an analogous description applies to the other memory cells. Although illustrated as a PMOS transistor, the transistor 140A can be an NMOS transistor. The transistor 140A includes a gate that is connected to the wordline WL1˜. The transistor 140A also includes a pair of nodes (e.g., source and drain), one connected to the bitline BL1˜ and the other connected to a first node of the capacitor 150A. The capacitor 150A has a second node that is connected to the corresponding second node of the capacitors 150B, 150C, 150D in each of the other DRAM memory cells 130B, 130C, 130D and also to a reference voltage Vb. In operation, depending on the gate voltage carried by the wordline WL1˜, the transistor 140A can be turned on or off. When the transistor 140A is turned on, current can flow through the source and drain nodes, meaning that the bitline BL1 is connected to the capacitor 150A.

In accordance with some example embodiments, the structure of the DRAM memory cell array (such as the one shown in FIGS. 1A and 1B) is modified in order to enable the execution of functions different from the data storage function of the DRAM memory cell array. An example modification could be reconfiguration of the connections within the DRAM memory cell array to transform the circuitries of the DRAM cell array into different circuitries.

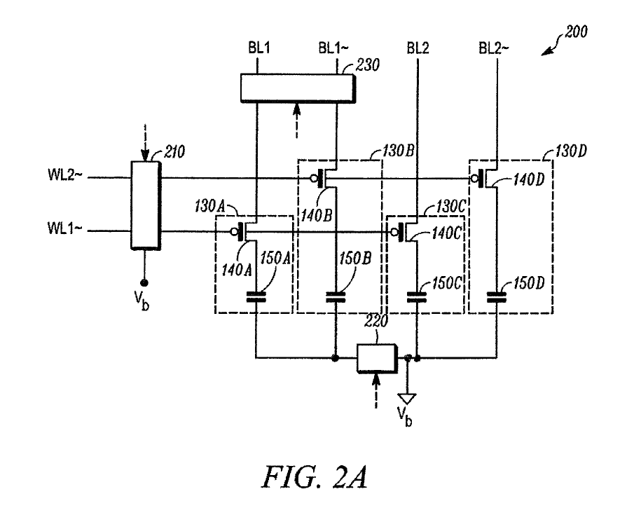

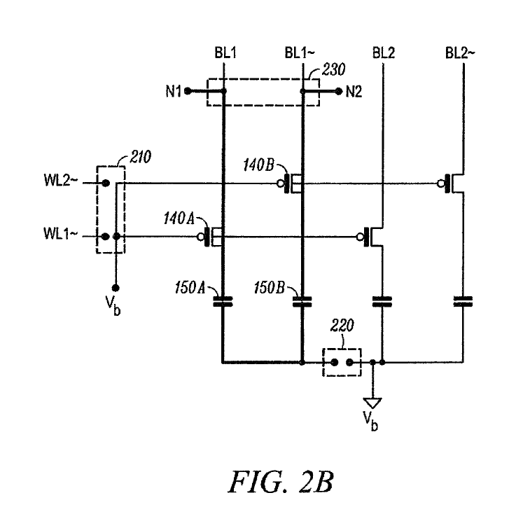

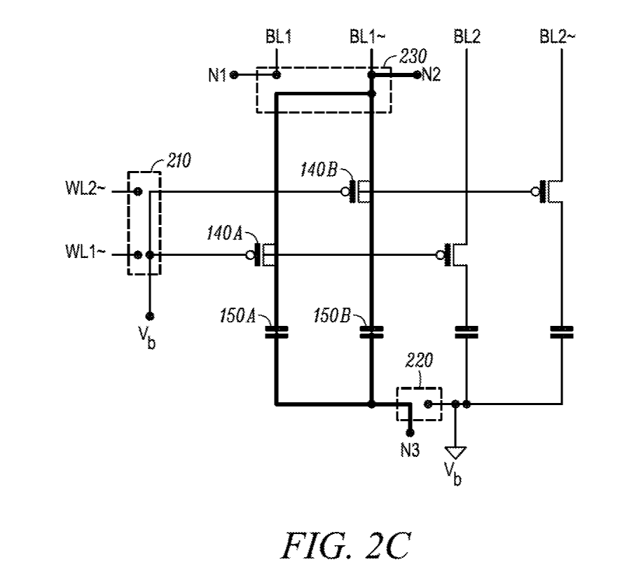

By way of non-limiting example, FIG. 2A shows a portion of a memory device 200 that includes the DRAM memory cells 130A, 130B, 130C, 130D of the previously described DRAM memory cell array. In the present embodiment, DRAM memory cells in different rows of the DRAM memory cell array are repurposed to provide a functionality other than a conventional data storage function. Specifically, in the illustrated embodiment, memory cells 130A, 130B are referred to as “repurposed” memory cells (while this embodiment describes two memory cells for convenience of illustration, it will be understood that also contemplated are alternative example embodiments where there are any suitable number, more than two, of repurposed memory cells).

To this end, the memory device 200 includes switching circuitry, which combines the capacitors 150A, 150B belonging to the repurposed DRAM memory cells 130A, 130B. Specifically, the switching circuitry can include:
a first switching element 210 between the wordlines WL1˜, WL2˜ and the transistors 140A, 140B of the repurposed DRAM memory cells 130A, 130B, respectively;
a second switching element 220 between the reference voltage Vb and a junction of the respective second nodes of the capacitors 150A, 1508 of the repurposed DRAM memory cells 130A, 130B; and
a third switching element 230 between the bitlines BL1/BL1˜ and first and second possible bulk capacitance terminals (denoted N1 and N2 in later described figures).

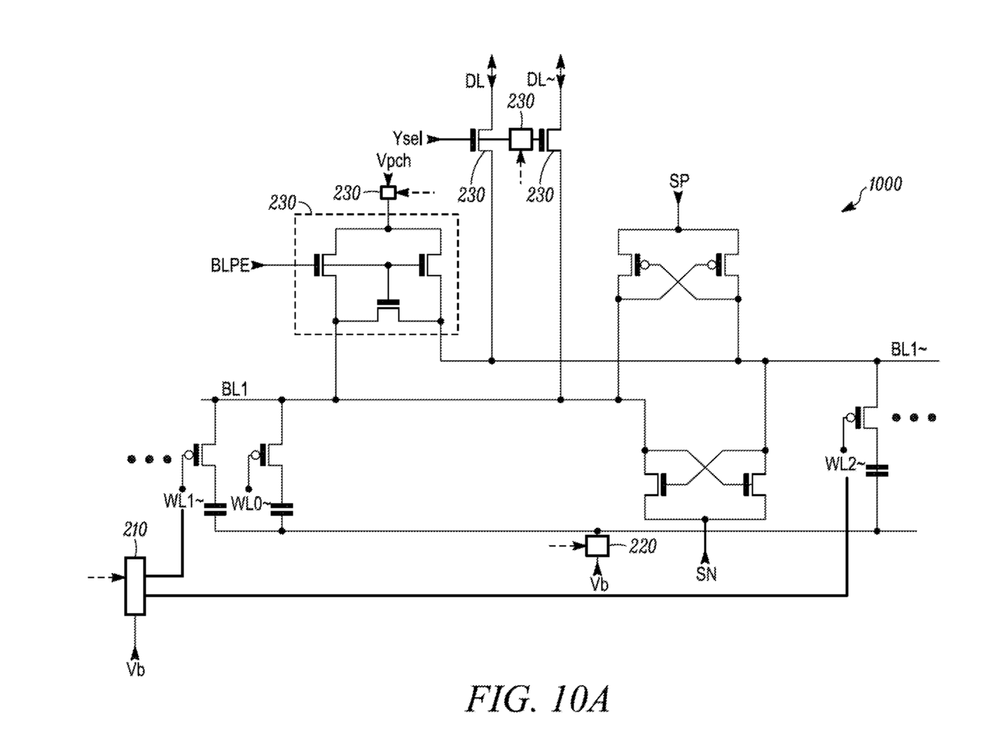

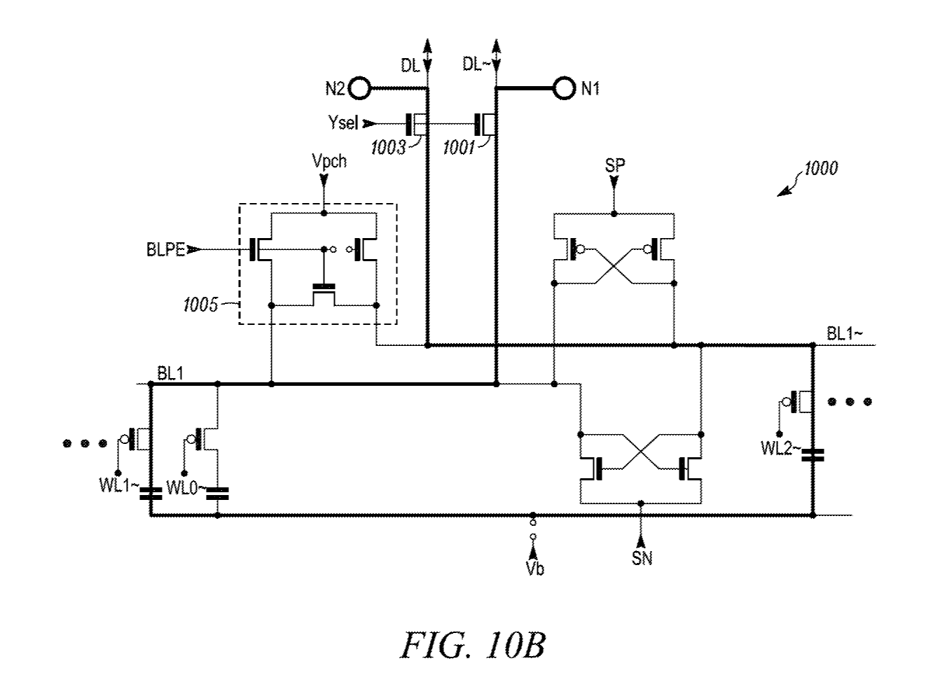

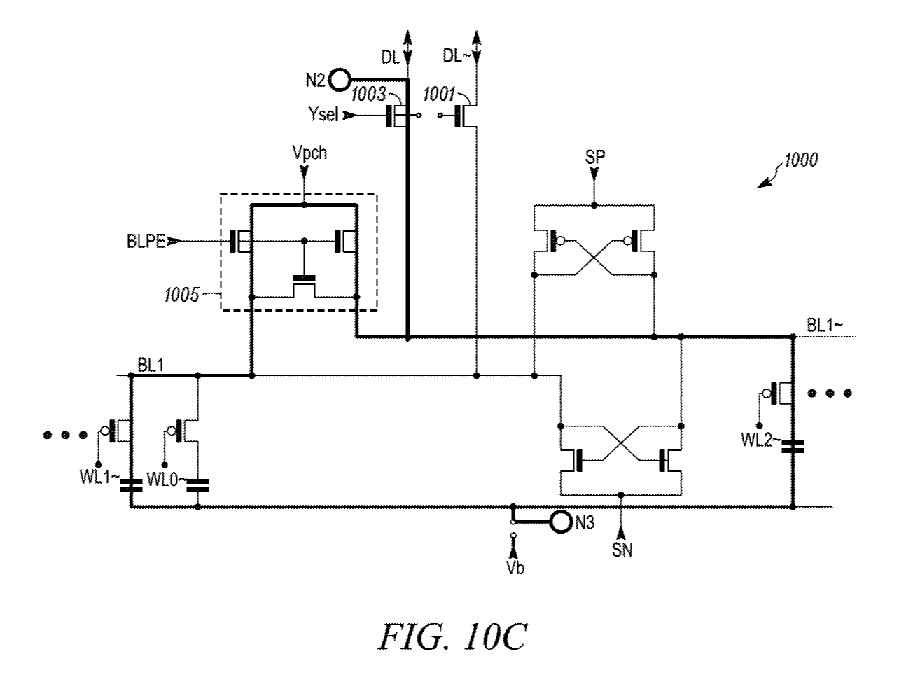

FIG. 10A shows more detail regarding possible placement of the first, second and third switching elements 210, 220, 230 within an embedded DRAM memory cell array. It is seen that the third switching element 230 can include a plurality of switches.

Dashed arrows in FIGS. 2A and 10A represent control signals being provided to the switching elements 210, 220, 230 of the switching circuitry (where dashed arrows are not shown, it is the gate of the illustrated transistor, forming part of one of the switching elements, that receives a control signal). These control signals may be supplied by controller circuitry (not shown) suitably configured for this purpose. The controller circuitry may be on the same integrated circuit chip as the DRAM memory cell array. Alternatively, the controller circuitry may be implemented on a separate integrated circuit chip. Also, alternatives to controller circuitry are contemplated including, for example, a processor or any suitable decision making circuitry. In some cases, the switching elements 210, 220, 230 include fuses, and the control signals are supplied once, at the time of manufacture, to permanently establish or interrupt connections among the components of the repurposed DRAM memory cells.

Through action of the switching circuitry, the capacitors 150A, 150B of the repurposed memory cells 130A, 130B can be combined in series or in parallel in order to provide a bulk capacitance at a pair of bulk capacitance terminals. FIG. 2B shows the case where the capacitors have been combined in series, while FIG. 2C shows the case where the capacitors have been combined in parallel. Both example embodiments will now be described.

With reference first to FIG. 2B, in order to provide a bulk capacitance in the case where the capacitors 150A, 150B of the repurposed memory cells 130A, 130B (in different rows) are combined in series, the switching circuitry can be responsive to the control signals in the following manner:
the first switching element 210 bypasses/overrides the wordlines WL1˜, WL2˜ and supplies an appropriate gate voltage in order to turn on the transistors 140A, 140B. For example, the gates of the transistors 140A, 140B can be driven with the reference voltage Vb;
the second switching element 220 disconnects the reference voltage

Vb from the junction of the respective second nodes of the capacitors 150A, 150B; and
the third switching element 230 provides a path from the bitline BL1 to the first bulk capacitance terminal (denoted N1) and a path from the complementary bitline BL1˜ to the second bulk capacitance terminal (denoted N2).

The thick line in FIG. 2B illustrates a path between bulk capacitance terminals N1 and N2, showing that the capacitors 150A, 150B in different rows of the DRAM memory cell array have been placed in series, and are isolated from certain other DRAM memory cells that continue to be purposed for data storage functionality.

FIG. 10B shows more details regarding the possible connections established by the first, second and third switching elements 210, 220, 230 when implemented within a portion of an embedded DRAM memory cell array 1000. It is seen that the reference voltage Vb has been disconnected. Also, a path has been provided from BL1 to the first bulk capacitance terminal N1 via transistor 1001 that is turned on by having a sufficiently high voltage signal applied to its gate, and has provided a path from BL1˜ to the second bulk capacitance terminal N2 via transistor 1003 that is turned on by having a sufficiently high voltage signal applied to its gate. It is noted that the embedded DRAM memory cell array 1000 includes bitline pre-charge equalization circuitry 1005 (which can be considered to be part of the switching element 230 shown in FIG. 2B) with all illustrated transistors turned off by applying a sufficiently low voltage signal to their gates. SP and SN signals are set up to turn off the cross-coupled inverters.

Reference with now be made to FIG. 2C which illustrates another example embodiment of two repurposed memory cells. While this example embodiment describes two memory cells for convenience of illustration, it will be understood that also contemplated are alternative examples embodiments where there are any suitable number, more than two, of repurposed memory cells.

Now in order to provide a bulk capacitance in the case where the capacitors 150A, 150B of the repurposed memory cells 130A, 130B (in different rows) are combined in parallel, the switching circuitry can be responsive to the control signals in the following manner:
the first switching element 210 bypasses/overrides the wordlines WL1˜, WL2˜ and supplies an appropriate gate voltage in order to turn on the transistors 140A, 140B. For example, the gates of the transistors 140A, 140B can be driven with the reference voltage Vb;
the second switching element 220 disconnects the reference voltage Vb from the junction of the respective second nodes of the capacitors 150A, 150B. This junction is connected to the second bulk capacitance terminal (denoted N3); and
the third switching element 230 joins the complementary pair of bitlines BL1/BL1˜ to the first bulk capacitance terminal (denoted N2).

The thick line in FIG. 2C illustrates a path between bulk capacitance terminals N2 and N3, showing that the capacitors 150A, 150B in different rows of the DRAM memory cell array have been placed in parallel, and are isolated from certain other DRAM memory cells that continue to be purposed for data storage functionality.

FIG. 10C shows more details regarding the possible connections established by the first, second and third switching elements 210, 220, 230 when implemented within an embedded DRAM memory cell array 1000. It is seen that the junction of the capacitors has been connected to the second bulk capacitance terminal N3, with reference voltage Vb having been disconnected. Also, a path is provided from bitlines BL1 and BL1˜ to the second bulk capacitance terminal via turned on bitline pre-charge equalization transistors of the circuitry 1005. Also, a switch between the transistors 1003 and 1001 is opened so that only transistor 1003 is turned on by a signal that is only applied to the gate of the transistor 1003 (the N1 terminal is unused in the illustrated example embodiment). Also, SP and SN remain set up to turn off the cross-coupled inverters.

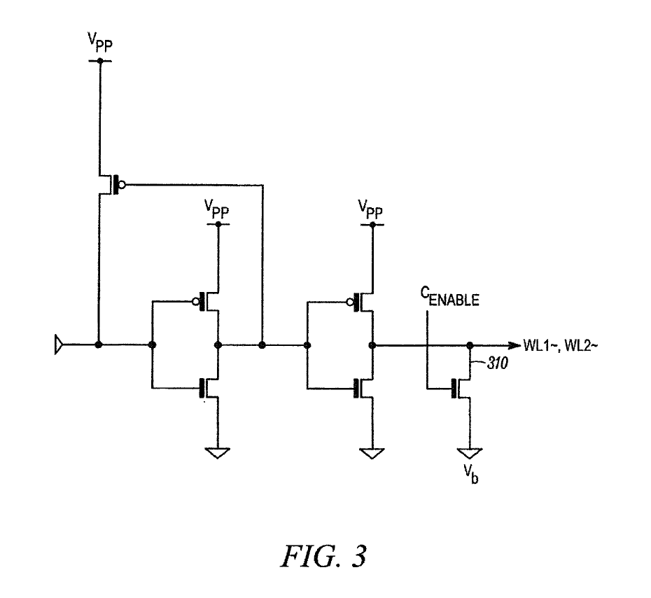

FIG. 3 is an example circuit diagram of a wordline override circuit that may be provided for the first switching element 210 in the memory device of FIGS. 2A-2C. The wordline override circuit includes a transistor 310 that has a pair of terminals (e.g., source and drain), one of which is connected to a wordline (e.g., WL1˜, WL2˜), the other of which is connected to the reference voltage Vb. The transistor 310 is capable of being turned on or off based on a C_{enable} signal. By asserting the C_{enable} signal, the wordlines WL1˜, WL2˜ are set to the reference voltage Vb, which then turns on the transistors 140A, 140B in the repurposed DRAM memory cells 130A, 130B.

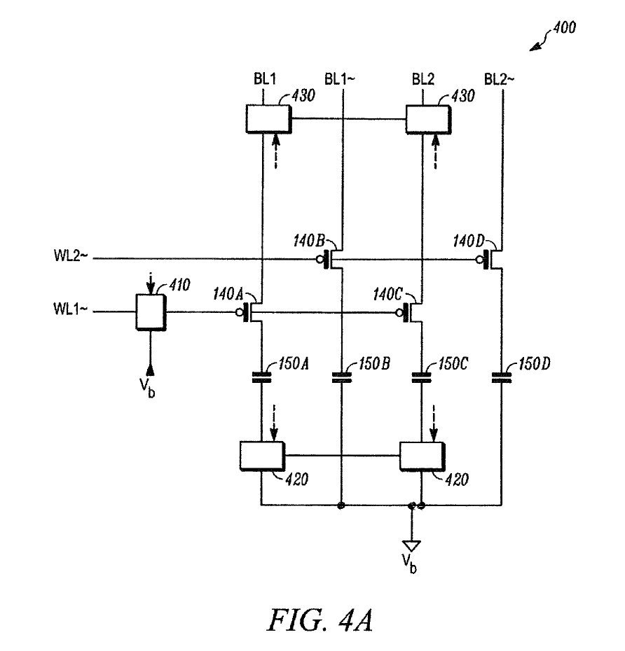

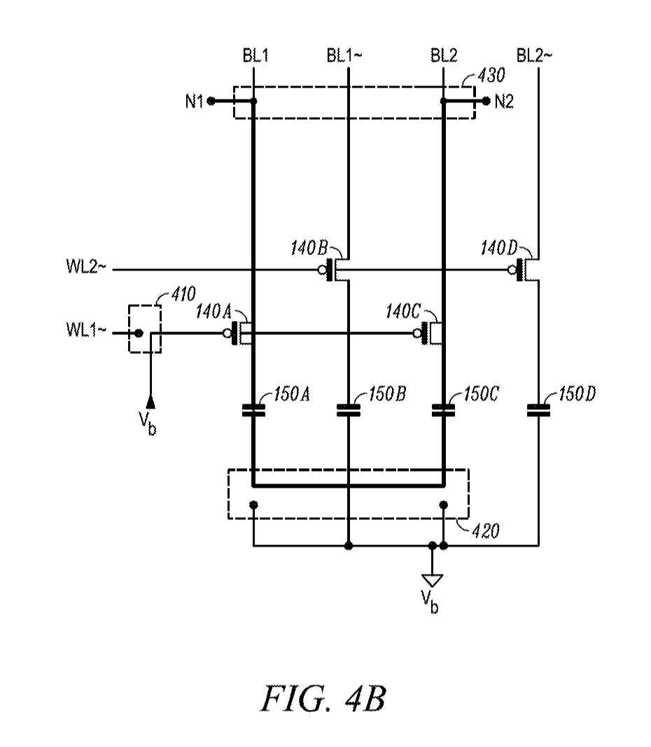

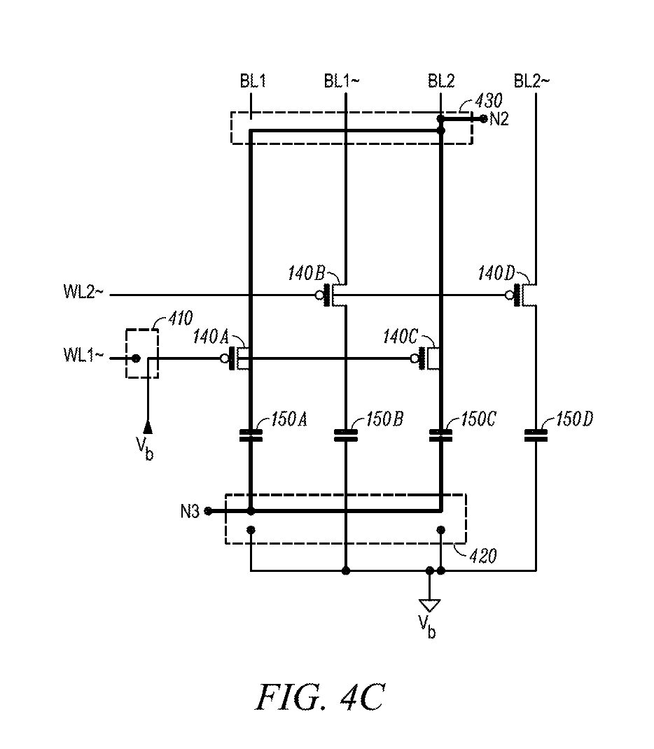

It will be seen that DRAM memory cells in different columns of the DRAM memory cell array may, in accordance with example embodiments, be repurposed to provide a functionality other than conventional data storage. Specifically, with reference to FIG. 4A, shown is a portion of a memory device 400 that includes the DRAM memory cells 130A, 130B, 130C, 130D of the earlier described DRAM memory cell array (see FIG. 2A) but in which memory cells 130A, 130C are “repurposed” memory cells (while this embodiment describes two memory cells for convenience of illustration, it will be understood that also contemplated are alternative example embodiments where there are any suitable number, more than two, of repurposed memory cells).

To this end, the memory device 400 includes switching circuitry, which combines the capacitors 150A, 150C belonging to the repurposed DRAM memory cells 130A, 130C. Specifically, the switching circuitry can include:
a first switching element 410 intercepting the wordline WL1˜ common to the transistors 140A, 140C of the repurposed DRAM memory cells 130A, 130C;
a second switching element 420 between the reference voltage Vb and the respective second node of each of the capacitors 150A, 150C of the repurposed DRAM memory cells 130A, 130C; and
a third switching element 430 that includes a portion between the bitline BL1 and the N1 terminal (FIG. 4B) and another portion between the bitline BL2 and the N2 terminal (FIG. 4B).

Referring again to FIG. 4A, dashed arrows represent control signals being provided to the switching elements 410, 420, 430 of the switching circuitry. These control signals may be supplied by controller circuitry (not shown) suitably configured for this purpose. The controller circuitry may be on the same integrated circuit chip as the DRAM memory cell array. Alternatively, the controller circuitry may be implemented on a separate integrated circuit chip. Also, alternatives to controller circuitry are contemplated including, for example, a processor or any suitable decision making circuitry. In some cases, the switching elements 410, 420, 430 include fuses, and the control signals are supplied once, at the time of manufacture, to permanently establish or interrupt connections among the components of the repurposed DRAM memory cells.

Through action of the switching circuitry, the capacitors 150A, 150C of the repurposed memory cells 130A, 130C can be combined in series or in parallel in order to provide a bulk capacitance at a pair of bulk capacitance terminals. FIG. 4B shows the case where the capacitors have been combined in series, while FIG. 4C shows the case where the capacitors have been combined in parallel. Both embodiments will now be described (while both example embodiments describe two memory cells for convenience of illustration, it will be understood that also contemplated are alternative example embodiments where there are any suitable number, more than two, of repurposed memory cells).

With reference first to FIG. 4B, in order to provide a bulk capacitance in the case where the capacitors 150A, 150C of the repurposed memory cells 130A, 130C (in different rows) are combined in series, the switching circuitry can be responsive to the control signals in the following manner:
the first switching element 410 bypasses/overrides the wordline WL1˜ and supplies an appropriate gate voltage in order to turn on the transistors 140A, 140C. For example, the gates of the transistors 140A, 140C can be driven with the reference voltage Vb using the circuit of FIG. 3;
the second switching element 420 disconnects the reference voltage Vb from the second node of the capacitor 150A and from the second node of the capacitor 150C, but maintains a connection between the respective second nodes of the capacitors 150A, 150C; and
the third switching element 430 provides a path from the bitline BL1 to the first bulk capacitance terminal (denoted N1) and a path from the bitline BL2 to the second bulk capacitance terminal (denoted N2).

The thick line in FIG. 4B illustrates a path between bulk capacitance terminals N1 and N2, showing that the capacitors 150A, 150C in different columns of the DRAM memory cell array have been placed in series, and are isolated from certain other DRAM memory cells that continue to be purposed for data storage functionality.

Turning now to FIG. 4C, in order to provide a bulk capacitance in the case where the capacitors 150A, 150C of the repurposed memory cells 130A, 130C (in different columns) are combined in parallel, the switching circuitry can be responsive to the control signals in the following manner:
the first switching element 410 bypasses/overrides the wordline WL1˜ and supplies an appropriate gate voltage in order to turn on the transistors 140A, 140C. For example, the gates of the transistors 140A, 140C can be driven with the reference voltage Vb using the circuit of FIG. 3;
the second switching element 420 disconnects the reference voltage

Vb from the second node of the capacitor 150A and from the second node of the capacitor 150C, but maintains a connection between the respective second nodes of the capacitors 150A, 150C, which is connected to the second bulk capacitance terminal (denoted N3); and
the third switching element 430 connects the bitlines BL1 and BL2 and joins them to the first bulk capacitance terminal (denoted N2).

The thick line in FIG. 4C illustrates a path between bulk capacitance terminals N2 and N3, showing that the capacitors 150A, 150C in different columns of the DRAM memory cell array have been placed in parallel, and are isolated from certain other DRAM memory cells that continue to be purposed for data storage functionality.

Thus, it will be appreciated that the reconfiguration of DRAM memory cells allows the formation of a bulk capacitor, in which the capacitors from two different DRAM memory cells are combined in series or in parallel, and isolated from other DRAM memory cells. The two terminals of the bulk capacitor are N1 and N2 in the series case, or N2 and N3 in the parallel case. In the series-type connection, the junction between the two capacitors is floating. As such, the top plate or buried layer is not shared by all DRAM memory cells in the array. It is also noted that the series-type connection allows for a higher voltage between N1 and N2 to be borne than across a single one of the capacitors. However, those skilled in the art will appreciate that the choice of serial-type connection versus parallel-type connection (or some combination of the two) will depend on various factors such as, for example, capacitor breaking voltage. It should also be appreciated that individual bulk capacitors can themselves be combined (e.g., connected in series or in parallel) to make combined bulk capacitors with different characteristics than any one individual bulk capacitor.

In accordance with example embodiments, reconfiguration of DRAM memory array circuitry can realize various different circuitries including charge pump circuitries, decoupling circuitries, analog-to-digital converter circuitries, digital-to-analog converter circuitries and voltage conversion circuitries (for example, DC-DC converter, switching regulator, etc.).

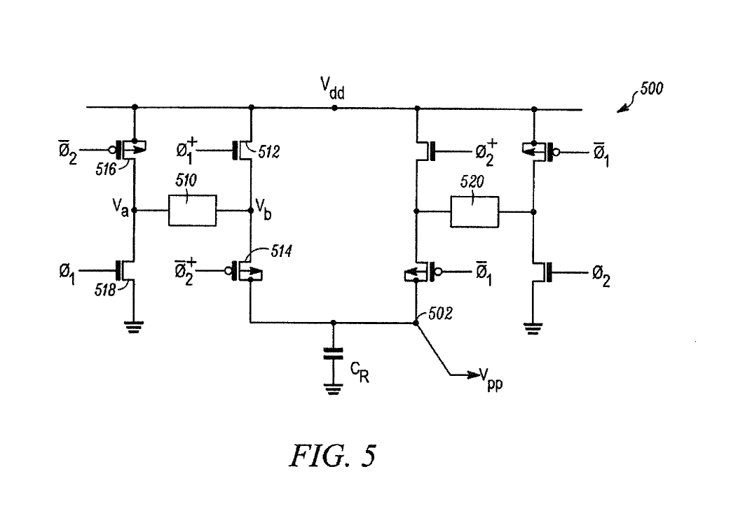

For example, FIG. 5 is a simplified circuit diagram of a Vpp pump 500 (or “charge pump”) which utilizes bulk capacitance provided by a memory device with repurposed DRAM memory cells in accordance with an example embodiment.

Specifically, the Vpp pump 500 receives a direct current (DC) supply voltage Vdd and includes an output terminal 502 for providing a DC output voltage Vpp. The Vpp pump 500 also includes a supply capacitor C_{R} connected between the output terminal 502 and a reference voltage.

The Vpp pump 500 further includes a switching circuit, which comprises a first pair of transistors 512, 514 and a second pair of transistors 516, 518. The first pair of transistors 512, 514 are connected in series between the supply voltage Vdd and the output terminal 502. (In this example embodiment, the transistor 512 is an n-channel MOSFET device and the transistor 514 is a p-channel MOSFET device.) The transistor 514 has a source and a substrate connected to the output terminal 502 and a drain connected to a node Vb and to a source of the transistor 512. A drain of the transistor 512 is connected to the supply voltage Vdd. The second pair of transistors 516, 518 are connected in series between the supply voltage Vdd and the reference voltage. (In this embodiment, the transistor 516 is a p-channel MOSFET device and the transistor 518 is an n-channel MOSFET device.) The transistor 516 has a source and a substrate connected to the supply voltage Vdd and a drain connected to a node Va and to a drain of the transistor 518. A source of the transistor 518 is connected to the reference voltage.

The switching circuit is operably configured to alternate between charging the capacitance of circuitry 510 to the supply voltage Vdd and connecting the circuitry 510 to the output terminal 502, in response to receiving switching signals φ₁, φ₁⁺, φ̅₂̅, φ̅₂̅⁺. As such, circuitry 510 is operable to provide a bulk capacitance between nodes Va and Vb on the left-hand side of the illustrated Vpp pump 500. (A similar description applies to circuitry 520 on the right-hand side of the illustrated Vpp pump 500, which is configured symmetrically with respect to the left-hand side.) Thus, the capacitance for charging and discharging the Vpp pump is provided by circuitries 510 and 520.

The circuitries 510, 520 can be circuitries comprising any suitable combination of portions of repurposed DRAM memory cell arrays as has been described above (see FIGS. 2A-2C, 4A-4C, 10A-10C, for example). In at least one example embodiment, the illustrated voltage pump circuit is implemented by reusing, to the extent that it is feasible to do so, as many already existing transistors (i.e. in the repurposed DRAM memory cell array) as possible.

The case where capacitors from memory cells are connected in series (whether they be from cells in different rows or in different columns) is of particular interest. Specifically, consider the case where each of the circuitries 510, 520 includes two capacitors placed in series. If the two capacitors (in each of the circuitries 510, 520) are substantially identical, then the voltage potential across either one of the capacitors taken alone will be only half the entire voltage potential (ignoring the transistors) than would be across a single charging capacitor as disclosed in U.S. Pat. No. 5,267,201. In this way, the requirement for voltage potential across both of the capacitors arranged in series can exceed the breaking voltage for an individual one of the capacitors.

For example, let the breaking voltage taken individually for either of the two capacitors be only a little more than Vdd/2. It will be noted that the two capacitors for the circuitry 510 can still be used in the illustrated circuit even if, say, Vb-Va might reach a maximum of Vdd (i.e., greater than the breaking voltage across either one of the two capacitors considered individually). Therefore, while the use of a single capacitor may not be feasible in some applications (such as a Vpp pump), the combination of multiple capacitors, as enabled by certain example embodiments, may make the use of such capacitors feasible in those applications.

The ready availability of numerous capacitors in a DRAM memory cell array may thus allow the requisite operational performance of a capacitor with a higher breaking voltage to be achieved inexpensively or more efficiently through repurposing certain DRAM memory cells.

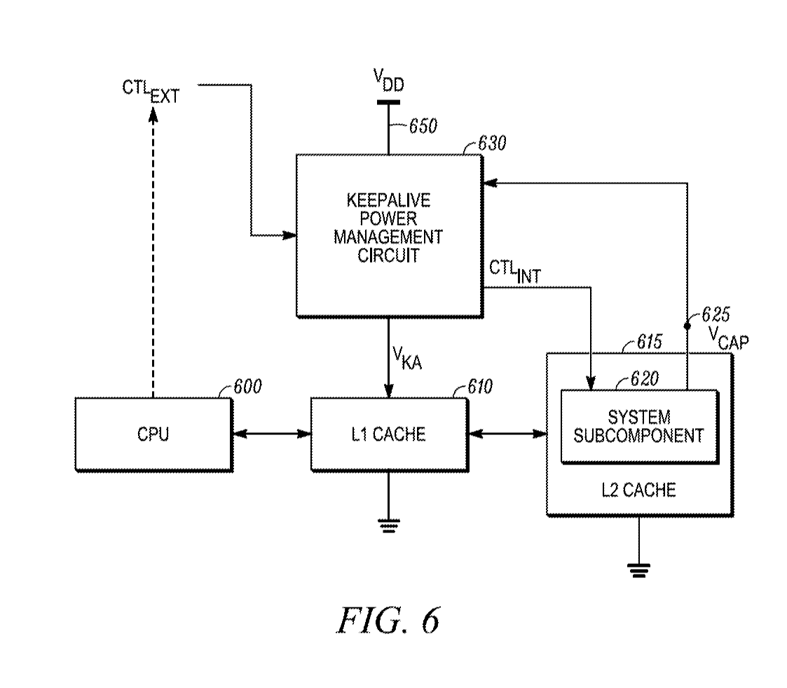

FIG. 6 is a functional block diagram of a system in accordance with another example embodiment. The system of FIG. 6 may be integrated within an electronic device, and particularly in a battery-powered electronic device such as, for example, a mobile phone, tablet, camera, laptop, alarm system, etc.

The system includes a CPU 600, a static random access memory (SRAM)-based L1 cache 610 and an embedded DRAM (eDRAM)-based L2 cache 615. Since the L1 cache 610 comprises volatile memory, it relies on a keepalive voltage V_{KA} for proper functioning. The keepalive voltage V_{KA} is supplied by a keepalive power management circuit 630. As understood by those skilled in the art, the L2 cache 615 may be sized larger than the L1 cache 610 in order to store more data.

As shown, the CPU 600 can communicate with and access data stored in the L1 cache 610 (e.g., first level checking to see if required data is stored in SRAM). If certain data cannot be found in the L1 cache 610, it may be stored in the L2 cache 615 and thus the CPU 600 is capable of communicating with and accessing data stored in the L2 cache 615 (e.g., second level checking). Of course, it will be understood that the communication between the CPU 600 and the L2 cache 615 is not necessarily direct: it is possible that there is some intermediate circuitry or subcomponent of the system through which data is retrieved and stored in the L2 cache 615. (Thus, the arrows shown in FIG. 6 are simply for convenience of illustration and not intended to exhaustively illustrate possible communication paths between the illustrated subcomponents of the system).

In some examples, the system illustrated in FIG. 6 may be entirely disposed on a single integrated circuit chip. In other examples, certain illustrated subcomponents of the system may be disposed on one integrated circuit chip, while other illustrated subcomponents of the system may be disposed on other integrated circuit chip(s).

Also shown in FIG. 6 is system subcomponent 620. In one example embodiment, the system subcomponent 620 can be a dual-purpose DRAM memory cell array with the ability to controllably carry out a data storage function or a bulk capacitance function, in dependence upon a control signal. The system subcomponent 620 can include a memory cell array and a switching element that receives an internal control signal CTL_{INT} from the keepalive power management circuit 630. The internal control signal CTL_{INT} indicates to the system subcomponent 620 whether it is to carry out the data storage function or the bulk capacitance function. While the system subcomponent 620 is shown as forming part of the L2 cache 615, this need not necessarily be the case.

In the illustrated example embodiment, when implementing the data storage function, the system subcomponent 620 functions as an extension of the L2 cache 615. On the other hand, when implementing the bulk capacitance function, the system subcomponent 620 functions as a DC-DC converter to provide power for the L1 cache 610. In that case, an output voltage V_{CAP} is therefore provided at a node 625 of the system subcomponent 620. In alternative example embodiments, the system subcomponent 620 provides some other function (for example, charge pump circuitry function, switching regulator function, decoupling function to remove switching noise associated with high frequency power supply operation, etc.)

The keepalive power management circuit 630 supplies the keepalive voltage V_{KA} to the L1 cache 610. Power for the keepalive voltage V_{KA} is drawn from one of two sources, depending on operational considerations dictated by the device into which the system of FIG. 6 is integrated. In a normal mode of operation of the device, the keepalive power management circuit 630 draws the keepalive voltage V_{KA} from a power source 650 at a power supply voltage V_{DD}. On the other hand, the device may have a “power saving” mode of operation, in which power is to be saved at the expense of potentially losing certain cached data. (Non-limiting examples of such power saving modes include “sleep mode” and “hibernate”.) In this power saving mode of operation, the keepalive voltage V_{KA} is supplied from the system subcomponent 620. Specifically, the keepalive voltage V_{KA} will be taken as the output voltage V_{CAP} provided by the system subcomponent 620. As such, during the power saving mode of operation, power will not be drawn from the power supply 650, resulting in less power being consumed by the device.

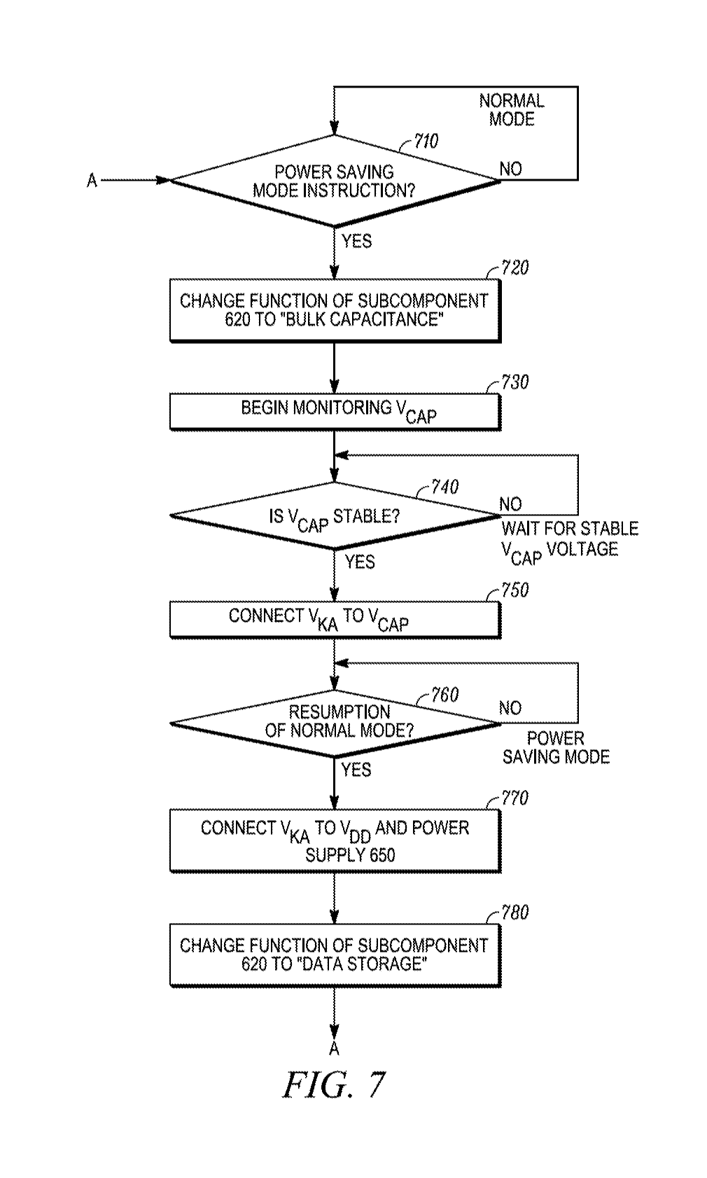

Operation of the keepalive power management circuit 630 is dependent on an external control signal CTL_{EXT}, which is provided by the device to indicate whether the device wishes to enter into or exit from the power saving mode of operation. (It is noted that the external control signal CTL_{EXT} may actually come from the CPU 600.) The device's instructions can be encoded in the level and/or transition patterns of the external control signal CTL_{EXT}. Further details regarding operation of the keepalive power management circuit 630 are now described with reference to the flowchart in FIG. 7.

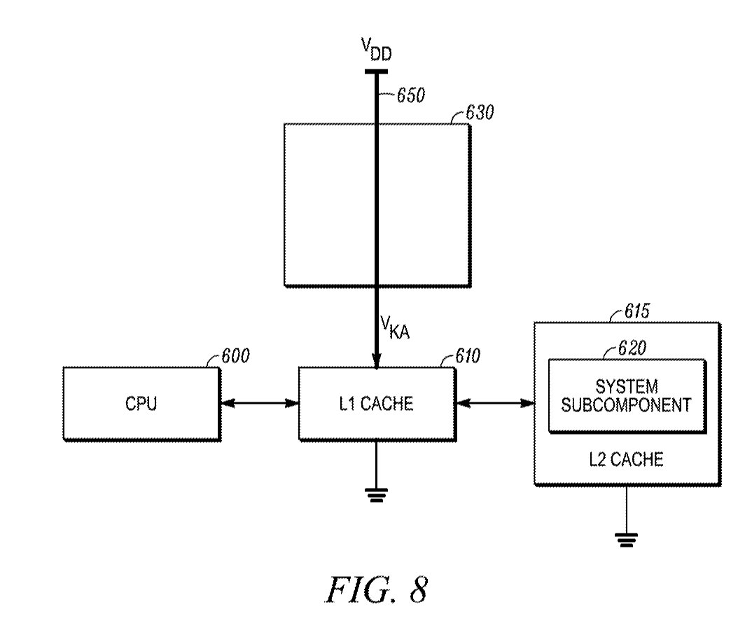

Before the start of the following description, it is assumed that the system subcomponent 620 implements a data storage function and that the keepalive voltage V_{KA} is being drawn from the power supply 650. This is seen in FIG. 8, where a thick arrow is shown between the power supply 650 and the L1 cache 610.

At action 710, the keepalive power management circuit 630 monitors the external control signal CTL_{EXT} and determines whether an instruction to enter the power saving mode of operation has been received. In the negative, this means that the device is still in the normal mode of operation and the keepalive power management circuit 630 loops back and re-executes action 710. However, once an instruction to enter the power saving mode of operation has been received, operation proceeds to action 720.

At action 720, the keepalive power management circuit 630 sends the internal control signal CTL_{INT} to the system subcomponent 620 to change its function from data storage to bulk capacitance. In response, the system subcomponent 620 will begin to implement the bulk capacitance function and provide a DC voltage as the output voltage V_{CAP} at the node 625.

At action 730, the keepalive power management circuit 630 begins monitoring the output voltage V_{CAP} from the system subcomponent 620.

At action 740, there is shown a loop during which the keepalive power management circuit 630 waits for the output voltage V_{CAP} from the system subcomponent 620 to stabilize.

At action 750, after the output voltage from the system subcomponent 620 has stabilized, the keepalive power management circuit 630 changes the power source for the keepalive voltage V_{KA}. Specifically, the keepalive voltage V_{KA} is now taken as the output voltage V_{CAP}. The power supply 650 is disconnected.

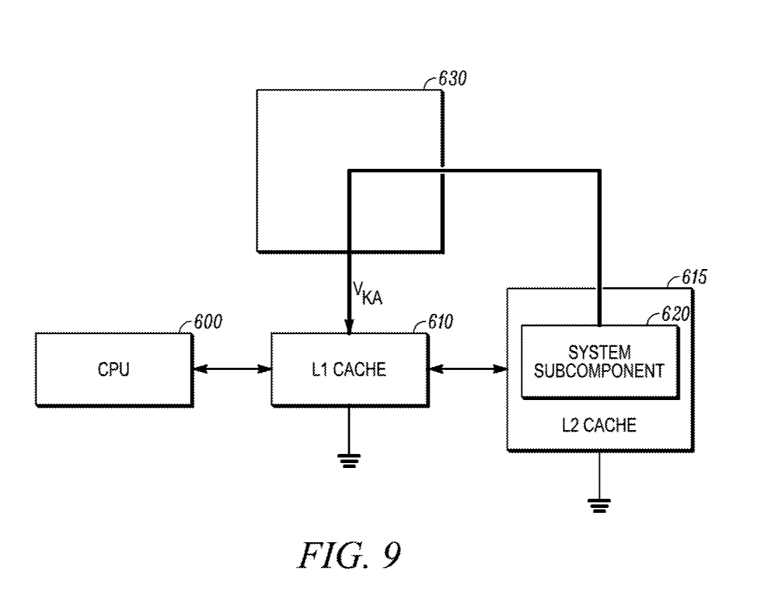

After execution of action 750, the situation resembles that illustrated in FIG. 9, where a thick arrow between the system subcomponent 620 and the L1 cache 610 shows that the system subcomponent 620 is acting as a capacitive power supply for the L1 cache 610 through the keepalive power management circuit 630. It will be appreciated that the capacitive power can be provided by DRAM memory cells that have been repurposed as has been previously described.

At action 760, there is shown a loop during which the keepalive power management circuit 630 monitors the external control signal CTL_{EXT} for a resumption of the normal (non-power-saving) mode of operation of the device.

At action 770, once it is learned that the device wishes to return to the normal mode of operation, the keepalive power management circuit 630 reconnects the power supply 650, from which the keepalive voltage V_{KA} will now be drawn.

At action 780, the keepalive power management circuit 630 ceases to monitor the output voltage V_{CAP,} and a command is sent via the internal control signal CTL_{INT} to cause the system subcomponent 620 to resume its data storage function.

After execution of action 780, the situation returns to that illustrated in FIG. 8, with a thick arrow representing the keepalive voltage V_{KA} being supplied to the L1 cache 610 from the power supply 650.

As has been mentioned above, it is possible to repurpose a portion of a DRAM memory cell array to provide a bulk capacitance, thereby effectively transforming the portion of the DRAM memory cell array into a bulk capacitor for a variety of functions. It is also envisaged that certain components of a DRAM memory cell array can be repurposed as additional switching and control elements to provide an even greater degree of flexibility.

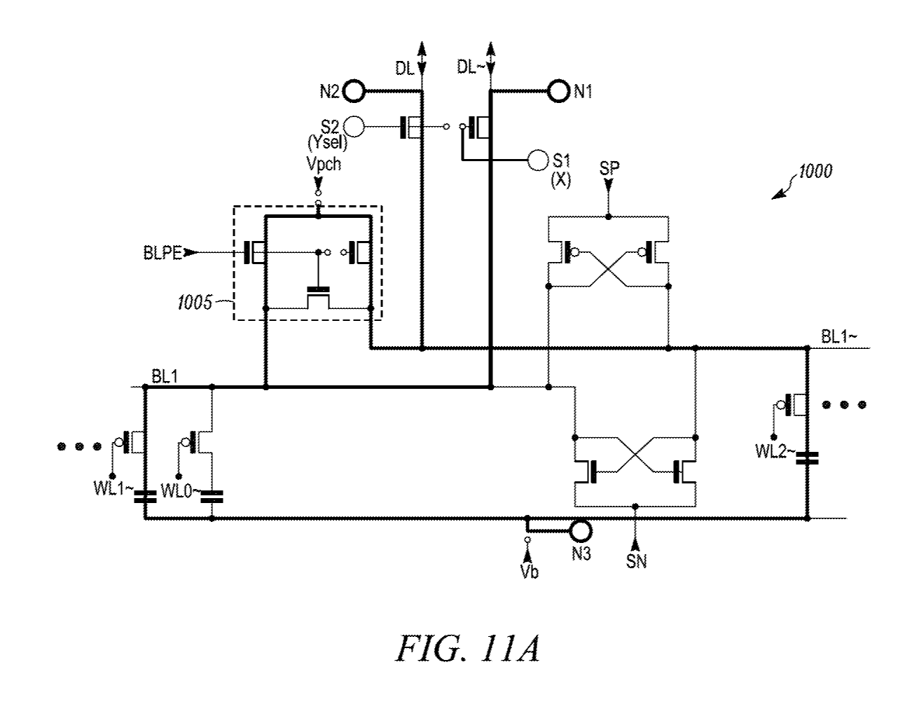

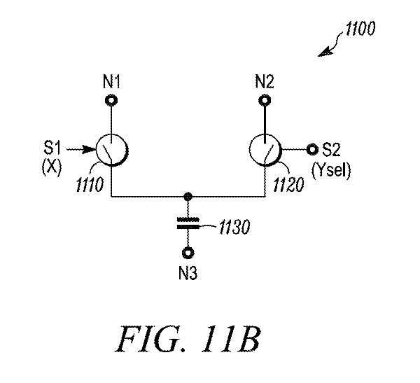

To this end, FIG. 11A is an example circuit diagram showing the embedded DRAM with three nodes N1, N2 and N3. Nodes N1 and N2 appear where they did in the configuration of FIG. 10B, while nodes N2 and N3 appear where they did in the configuration of FIG. 10C. In this example embodiment, the column address selection signal Ysel and a suitable signal X can be used as control switches at switching nodes S2 and S1, respectively. Just as described in connection with FIG. 10C, the bitline pre-charge equalization transistors of the circuitry 1005 are turned on.

An equivalent circuit of the circuit diagram of FIG. 11A is shown in FIG. 11B, illustrating the three nodes N1, N2 N3, in addition to the two switching nodes S1 and S2, where the signals X and Ysel are provided, respectively. The switching nodes S1, S2 control the state of switches 1110, 1120. Also shown in the equivalent circuit is a single capacitor 1130, which represents the effective capacitance of the parallel connection of the capacitors of the repurposed DRAM memory cells. The functional unit depicted by the equivalent circuit of FIG. 11B can be referred to as a “block”.

Blocks such as the one formed by the configuration in FIG. 11A (and represented by the circuit of FIG. 11B) can be used in a variety of applications. For example, the X and Ysel signals can be varied to achieve DC-DC converter control. More specifically, the X and Ysel signals are provided to the switching nodes S1 and S2, which connect to the gates of transistors 1110, 1120 on reconfigured paths of the DRAM memory cell array. Thus, depending on the gate voltages, paths through the capacitor 1130 of the DC-DC converter can be opened or closed.

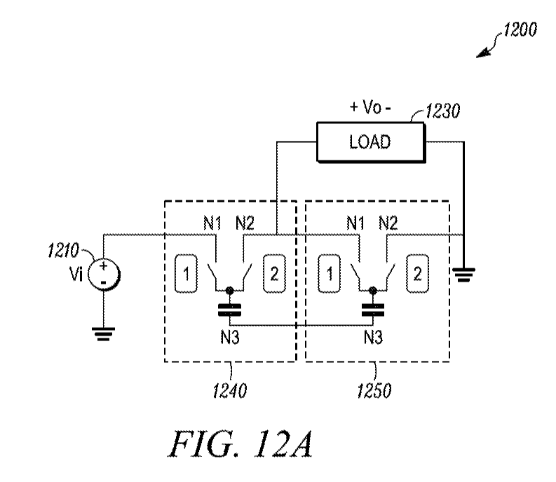

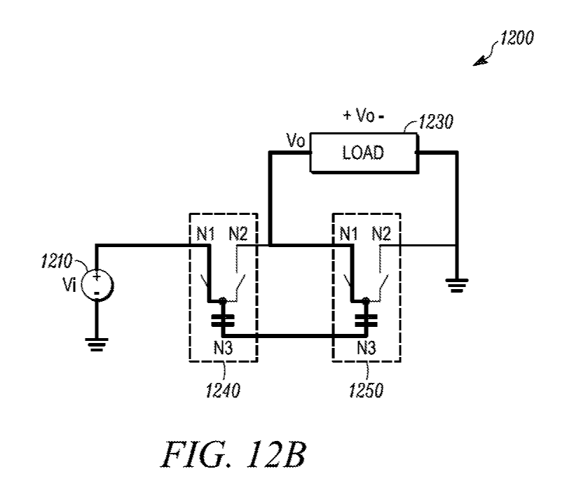

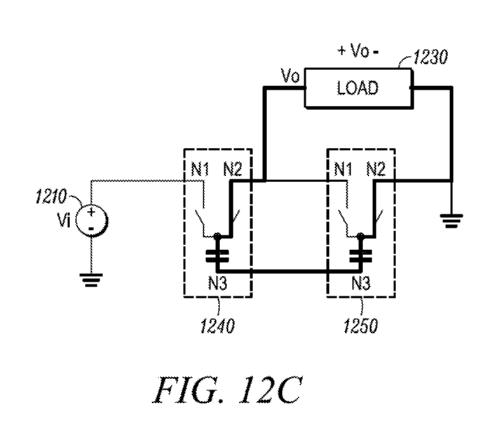

In particular, with reference to FIG. 12A, there is shown a DC-DC converter 1200 comprising an input voltage source 1210, a load (such as one or more digital circuits) 1230, a first block 1240 and a second block 1250. Node N1 of the first block 1240 is connected to the input voltage source 1210. Node N2 of the first block 1240 is connected to node N1 of the second block 1250 and is also connected across the load 1230. Nodes N3 of the first and second blocks 1240, 1250 are connected together, and node N2 of the second block 1250 is connected to the reference. The DC-DC converter 1200 may comprise additional components that have been omitted for simplicity, such as resistors, inductors and/or capacitors.

Also shown in FIG. 12A are boxes marked “1” and “2”. These refer to two different phases of the DC-DC converter 1200. Boxes marked “1” indicate the switches that are closed during the first phase, with boxes marked “2” being open during this first phase. The result, which is shown in thick lines in FIG. 12B, is that the potential from the input voltage source 1210 is applied across the load 1230, while each of the blocks 1240, 1250 builds up its capacitance. On the other hand, boxes marked “2” indicate the switches that are closed during the second phase, with boxes marked “1” being open during this second phase. The result, which is shown in thick lines in FIG. 12C, is that the capacitances that had been built up by the two blocks 1240, 1250 are placed in series, resulting in twice the voltage being placed across the load 1230.

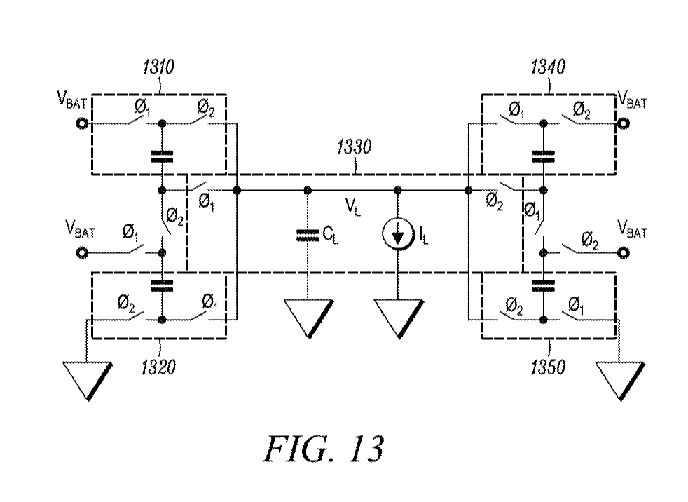

Other uses for blocks such as the one described with reference to FIGS. 11A and 11B are possible. For example, such blocks could be used in a switched-capacitor step-down DC-DC converter. To this end, FIG. 13 shows a two-way interleaved G2BY3 gain setting implemented as a 2-way interleaved structure to provide voltages below ⅔ of the input voltage V_{BAT}. The converter can incorporate some of the teachings of Ramadass et al., “Fully-Integrated Switched-Capacitor Step-Down DC-DC Converter With Digital Capacitance Modulation in 45 nm CMOS”, IEEE Journal of Solid-State Circuits, Vol. 45, No. 12, December 2010, pp. 2557-2565, hereby incorporated by reference herein. Also shown in FIG. 13 are dashed boxes 1310, 1320, 1330, 1340, 1350. Each box includes two switches and a capacitor. In accordance with some examples, the components within the dashed boxes could be implemented using blocks such as the one described with reference to FIGS. 11A and 11B, based on repurposed DRAM memory cells.

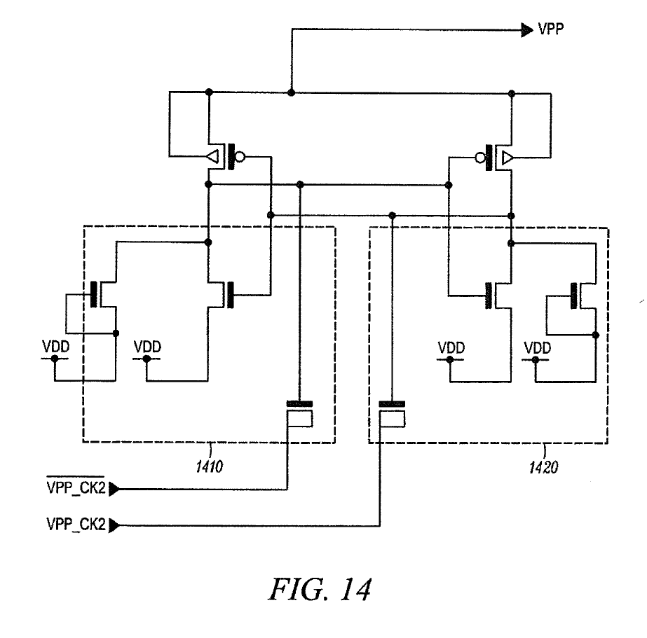

Also, blocks such as the one described with reference to FIGS. 11A and 11B could be used in a high voltage charge pump as illustrated in FIG. 14. Shown are dashed boxes 1410, 1420, each including two switches and a capacitor. In accordance with some examples, the components within the dashed boxes could be implemented using blocks such as the one described with reference to FIGS. 11A and 11B, based on repurposed DRAM memory cells.

One particularly suitable physical implementation of a repurposed DRAM memory cell uses metal-insulator-metal (MIM) capacitors. MIM capacitors can be vertical, with horizontal metal plates; lateral, with vertical plate; or mixed, employing capacitance between both vertically-separated and horizontally-separated plates. In some applications, special insulator layers are provided for optimized capacitor performance. In others, existing dielectrics are used, such as the inter-metal dielectrics which separate metal interconnections.

In the case of a DRAM memory array, where space is at a premium, two proposed implementations of MIM capacitors used in the DRAM memory cells include stack-type capacitors and trench-type capacitors.

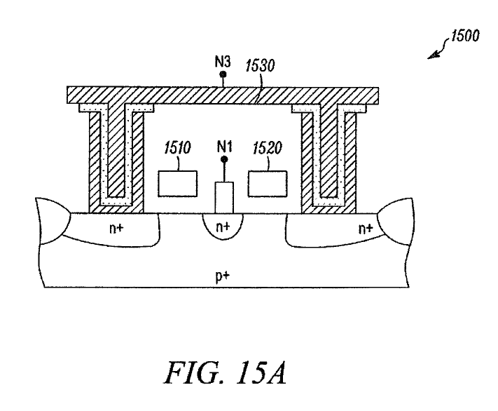

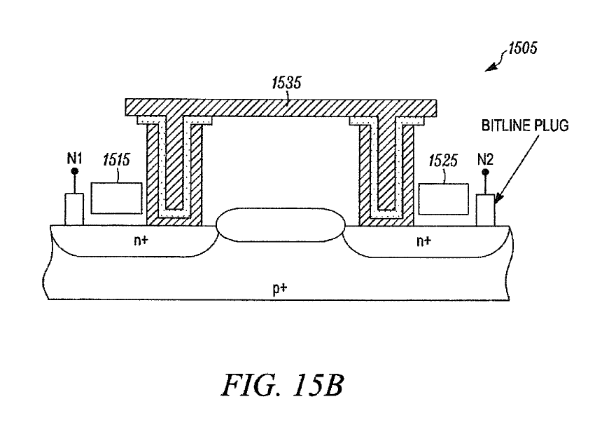

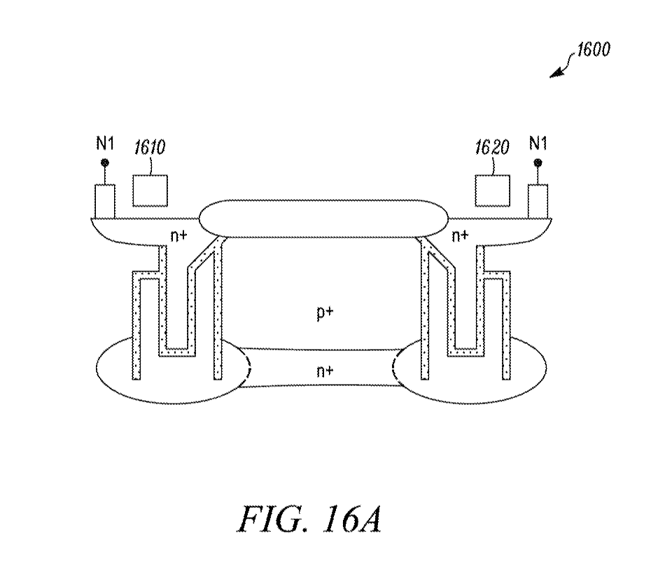

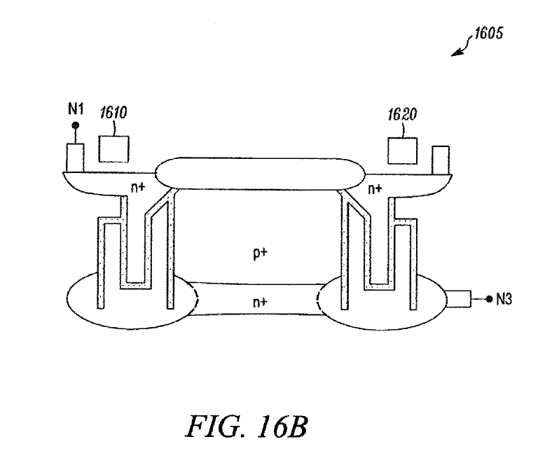

Thus, where DRAM memory cells are repurposed to provide a bulk capacitance, the MIM capacitors of two or more DRAM memory cells are connected (in series or in parallel). Considering that two non-limiting examples of MIM capacitors are stack-type capacitors and trench-type capacitors, this yields four possibilities that are now considered with reference to FIGS. 15A, 15B, 16A and 16B, by way of non-limiting example.

FIG. 15A is a diagram of an example embodiment where two MIM capacitors are connected in parallel in accordance with a stack-type implementation in order to produce a bulk capacitor 1500. For its part, FIG. 15B is a diagram of an example embodiment where two MIM capacitors are connected in series in accordance with a stack-type implementation in order to produce a bulk capacitor 1505.

In FIG. 15A, a large single plate 1530 is employed. The plate 1530 extends horizontally between the two capacitors, linking them together electrically. In this embodiment, N1 and N3 indicate suitable locations for the two nodes of the bulk capacitor 1500. Specifically, capacitor terminal N3 is provided at the plate 1530, and capacitor terminal N1 is at a location in the N+ layer between the vertical structures of the capacitors. Electrical connections 1510, 1520 are provided, to which is applied a gate voltage. The electrical connections 1510, 1520 can be direct electrical connections to wordlines WL1˜, WL2˜, etc., and the gate voltage can be a wordline voltage.

Turning to FIG. 15B, a large single plate 1535 is employed. The plate 1535 extends horizontally between the two capacitors, linking them together electrically. One main difference from FIG. 15A is the location of the capacitor terminals of the bulk capacitor 1505, which are indicated by N1 and N2. In this example embodiment, neither capacitor terminal is located between the vertical structures of the capacitors, but rather both N1 and N2 are situated in the N+ layer at opposite locations relative to each other (i.e., the vertical structures of the capacitors are situated between the N1 and N2 terminals). Electrical connections 1515, 1525 are provided, to which is applied a gate voltage. The electrical connections 1515, 1525 can be direct electrical connections to wordlines WL1˜, WL2˜, etc., and the gate voltage can be a wordline voltage.

FIG. 16A is a diagram of an example embodiment where two MIM capacitors are connected in parallel in accordance with a trench-type implementation in order to produce a bulk capacitor 1600. For its part, FIG. 16B is a diagram of an example embodiment where two MIM capacitors are connected in series in accordance with a trench-type implementation in order to produce a bulk capacitor 1605.

In FIGS. 16A and 16B, a region in the N+ buried layer extends between the two capacitors, linking them together electrically. Bulk capacitor terminal N1 is located at the top of one of the capacitors in an N+ region of that capacitor. In FIG. 16A, bulk capacitor terminal N2 is located at the top of the other capacitor in an N+ region of that capacitor. In FIG. 16B, bulk capacitor terminal N3 is in the N+ buried layer.

In both FIGS. 16A and 16B, electrical connections 1610, 1620 are provided, to which is applied a gate voltage. The electrical connections 1610, 1620 can be direct electrical connections to wordlines WL1˜, WL2˜, etc., and the gate voltage can be a wordline voltage.

The use of MIM capacitors may have various impacts. For example, an impact of using MIM capacitors in the Vpp pump 500 of FIG. 5 may be to reduce the die space taken up by the Vpp pump 500 relative to a Vpp pump that uses conventional MOS capacitors as charging capacitors. This is because a conventional MOS capacitor is a planar capacitor which takes up a relatively larger die area, whereas a MIM capacitor may have a structure that is primarily vertical for facilitating a greater capacitance per unit area. As a result, because each of the circuitries 510, 520 of the illustrated example Vpp pump 500 of FIG. 5 may be smaller than the charging capacitor in a conventional Vpp pump, the die space taken up by the Vpp pump 500 as a whole may be smaller.

It will be appreciated that in some example embodiments, repurposing of DRAM memory cells can be done dynamically, based on a control signal. This can be achieved through the use of transistors or other forms of switches. In other example embodiments, it may be desired or preferable to repurpose the DRAM memory cells permanently, at the time of manufacture. Such “static” repurposing can be achieved by using fuses or equivalents thereof. In some cases, repurposing of DRAM cells may be carried out at the time of manufacture based on testing that is conducted on a DRAM memory cell array. Specifically, an integrated circuit design for a DRAM memory cell array may include regions of the memory array that can be isolated from one another, if need be, through activation of a set of fuses. Activation of the fuses may be done after testing of the DRAM array and in response to identifying that a certain memory cell or group of memory cells in a given region does not perform adequately. In that case, the appropriate fuses could be activated, and the region in question can be not only isolated from the other regions of the DRAM memory cell array, but also repurposed as described earlier in this specification to provide a bulk capacitance.

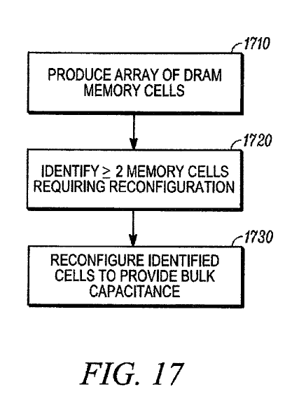

Thus, with reference to FIG. 17, there may be provided a method of manufacturing a semiconductor memory device, which includes action 1710, at which an array of DRAM memory cells is produced. At action 1720, at least two of the DRAM memory cells are found to require reconfiguration (e.g., by virtue of being defective as memory cells). At action 1730, the identified memory cells are reconfigured by connecting their respective capacitors in one of the previously described ways to provide a bulk capacitance between a first node (N1) and a second node (N2 or N3).

Thus, the provision of fuses at carefully selected locations in the DRAM memory cell array can act as a preventative measure to not only salvage what may be a significant remaining portion of the DRAM memory cell array, but also to convert what would otherwise be considered a defective region into a bulk capacitor that can be used in a variety of circuitries with non-data-storage functions (including charge pump circuitries, decoupling circuitries, analog-to-digital converter circuitries, digital-to-analog converter circuitries and voltage conversion circuitries, to name a few non-limiting examples).

It will be understood that when an element has herein been referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in like fashion (i.e., “between” versus “directly between”, “adjacent” versus “directly adjacent”, etc.).

As a further final note, it will be understood that certain adaptations and modifications of the described embodiments can be made. For example, in some example embodiments, not all access transistors in all reconfigured DRAM cells are necessarily used. For such unused access transistors, it is possible to make a conducting connection between drain and source (or alternatively circuitry can be changed in some other manner to at least effectively remove unused access transistors). Thus, in summary, the above discussed embodiments are considered to be illustrative and not restrictive.

What is claimed is:

1. A semiconductor device comprising:
a plurality of DRAM memory cells, each of the DRAM memory cells comprising a capacitor; and
switching circuitry configured to be switched to a state in which the switching circuitry connects capacitors of at least two of the DRAM memory cells together to provide a bulk capacitance between a first node and a second node,
wherein the at least two DRAM memory cells are repurposed in the state.

2. The semiconductor device of claim 1, wherein when the switching circuitry is switched to said state, the capacitors of the at least two DRAM memory cells are connected in series.

3. The semiconductor device of claim 1, wherein when the switching circuitry is switched to said state, the capacitors of the at least two DRAM memory cells are connected in parallel.

4. The semiconductor device of claim 1, wherein each of the at least two DRAM memory cells further comprises a transistor capable of being turned on or off based on a gate voltage.

5. The semiconductor device of claim 4, wherein the switching circuitry comprises a circuit for controlling the gate voltage, and wherein when the switching circuitry is switched to said state, the gate voltage is set to and held at a level that turns on the transistor.

6. The semiconductor device of claim 4, wherein the transistor of each of the at least two DRAM memory cells is a MOS transistor.

7. The semiconductor device of claim 4, wherein for each of the at least two DRAM memory cells, the respective capacitor has a first node and a second node, and the respective transistor has a first node and a second node through which current flows when the transistor is turned on, and wherein the second node of the respective transistor is connected to the first node of the respective capacitor.

8. The semiconductor device of claim 7, wherein the second node of the capacitor of a first one of the at least two DRAM memory cells is connected to the second node of the capacitor of a second one of the at least two DRAM memory cells.

9. The semiconductor device of claim 7, wherein the first node is a first bulk capacitance node, wherein the second node is a second bulk capacitance node, the first bulk capacitance node being connected to the first node of the transistor of a first one of the at least two DRAM memory cells, and the second bulk capacitance node being connected to the first node of the transistor of a second one of the at least two DRAM memory cells.

10. The semiconductor device of claim 7, wherein the first node is a first bulk capacitance node, wherein the second node is a second bulk capacitance node, the first bulk capacitance node being connected to the first node of the transistor of each of the at least two DRAM memory cells, and the second bulk capacitance node being connected to the second node of the capacitor of each of the at least two DRAM memory cells.

11. The semiconductor device of claim 1, wherein the DRAM memory array includes a plurality of DRAM memory cells other than the at least two DRAM memory cells, and which are configured for data storage.

12. The semiconductor device of claim 11, wherein the capacitor of each of the other DRAM memory cells is connected to a common voltage reference.

13. The semiconductor device of claim 12, wherein the switching circuitry comprises a circuit for isolating the capacitors of the at least two DRAM memory cells from the voltage reference when the switching circuitry is switched to the first state.

14. The semiconductor device of claim 13, wherein said state is a first state, wherein the circuit is further operable for connecting the capacitors of the at least two DRAM memory cells to the voltage reference when the switching circuitry is switched to a second state different from the first state.

15. The semiconductor device of claim 14, wherein when the switching circuitry is in the second state, the at least two DRAM memory cells are configured for data storage.

16. The semiconductor device of claim 1, wherein the DRAM memory cells are within a DRAM memory array of the semiconductor device and are arranged in a matrix of rows and columns, and wherein the at least two DRAM memory cells include DRAM memory cells from at least two of the columns of the DRAM memory array.

17. The semiconductor device of claim 1, wherein the DRAM memory cells are within a DRAM memory array of the semiconductor device and are arranged in a matrix of rows and columns, and wherein the at least two DRAM memory cells include DRAM memory cells from at least two of the rows of the DRAM memory array.

18. The semiconductor device of claim 1, wherein the DRAM memory cells are within a DRAM memory array of the semiconductor device and are arranged in a matrix of rows and columns, and wherein each of the DRAM memory cells is connected to a wordline for the respective row and to a bitline for the respective column, and wherein the first node is connected to a first one of the bitlines.

19. The semiconductor device of claim 18, wherein the second node is connected to a second one of the bitlines.

20. The semiconductor device of claim 18, wherein each of the DRAM memory cells in the DRAM memory array comprises a transistor capable of being turned on or off based on the voltage on the respective wordline.

21. The semiconductor device of claim 20, wherein when the switching circuitry is in said state, the gate voltage for each of the at least two DRAM memory cells overrides the voltage on the respective wordline.

22. The semiconductor device of claim 1, wherein the switching circuitry is permanently switched into said state during manufacture of the device.

23. The semiconductor device of claim 22, further comprising a fuse that enables the switching circuitry to be permanently switched to said state during manufacture of the device.

24. The semiconductor device of claim 1, wherein the state is a first state, and wherein when the switching circuitry is in a second state different from the first state, the at least two DRAM memory cells are configured for data storage.

25. The semiconductor device of claim 24, wherein the switching circuitry is responsive to a control signal to controllably switch to the first state or the second state.

26. The semiconductor device of claim 25, integrated into an electronics product, wherein the control signal is indicative of an instruction to switch to the first state when the electronics product is in a power saving mode of operation.

27. The semiconductor device of claim 26, wherein the control signal is indicative of an instruction to switch to the second state when the electronics product is no longer in the power saving mode of operation.

28. The semiconductor device of claim 1, further comprising a first switching element that selectably establishes or interrupts an electrical path to the first node and further comprising a second switching element that selectably establishes or interrupts an electrical path to the second node.

29. The semiconductor device of claim 28, wherein at least one of the first and second switching elements is implemented at least in part by a column address selection circuit.

30. The semiconductor device of claim 1, wherein the switching circuitry is comprised of NMOS transistors.

31. The semiconductor device of claim 1, wherein the bulk capacitance is utilized in a charge pump application.

32. The semiconductor device of claim 1, wherein the bulk capacitance is utilized in a decoupling application.

33. The semiconductor device of claim 1, wherein the bulk capacitance is utilized in a voltage conversion application.

34. The semiconductor device of claim 1, wherein the capacitor in each of the DRAM memory cells is a metal-insulator-metal (MIM) capacitor.

35. The semiconductor device of claim 34, wherein the capacitor in each of the DRAM memory cells is a stack-type capacitor.

36. The semiconductor device of claim 34, wherein the capacitor in each of the DRAM memory cells is a trench-type capacitor.

37. A method of manufacture comprising:
producing a Dynamic Random Access Memory (DRAM) memory array including a plurality of DRAM memory cells, each of the DRAM memory cells comprising a capacitor; and
identifying at least two of the DRAM memory cells to be reconfigured;
reconfiguring the identified memory cells by connecting the capacitors of the identified memory cells together to provide a bulk capacitance between a first node and a second node.

38. Use of a first portion of a DRAM memory cell array to provide a bulk capacitance in an electronic device, while a second portion of the DRAM memory cell array provides a data storage function.

39. A system, comprising:
a primary circuit of an electronic device drawing power from a power source when the electronic device is in a normal mode of operation;
a semiconductor device comprising an array of DRAM memory cells, at least part of the semiconductor device being configured to respond to a command to implement a data storage function or a bulk capacitive power supply function for the primary circuit; and
a control circuit, the control circuit being responsive to receipt of a control signal to command the at least part of the semiconductor device to implement the data storage function when the electronic device is in the normal mode of operation and to implement the bulk capacitive power supply function for the primary circuit when the electronic device is in a power saving mode of operation.
